(19) United States
(12) Patent Application Publication
(10) Pub. No.: US 2026/0123523 A1
(43) Pub. Date: Apr. 30, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Ting-Hao CHEN, Taichung City (TW); Hsuan-Jen WANG, Taichung City (TW); Wei-Shen HUNG, Taichung City (TW); Hsiao-Ping LAI, Taichung City (TW)

(73) Assignee: SILICONWARE PRECISION INDUSTRIES CO., LTD., Taichung City (TW)

(21) Appl. No.: 19/073,601

(22) Filed: Mar. 7, 2025

(30) Foreign Application Priority Data
Oct. 25, 2024 (TW) 113140835

(51) Int. Cl. H01L 23/18; H01L 21/56; H01L 23/00; H01L 23/31; H01L 23/48

(52) U.S. Cl. CPC H10W 76/42; H10W 20/20; H10W 74/014; H10W 74/114; H10W 72/0198; H10W 90/724

(57) ABSTRACT

Provided are an electronic package and a manufacturing method thereof, which include disposing a stress buffer on a scribe line between a plurality of electronic components; forming an encapsulation layer encapsulating the plurality of electronic components and the stress buffer; removing the stress buffer, and cutting along the scribe line to separate each of the electronic components, thereby a problem of warpage can be avoided by reducing an amount of the encapsulation layer.

### BACKGROUND

### 1. Technical Field

The present disclosure relates to a semiconductor packaging technology, and more particularly, to an electronic package that can reduce package warpage and a manufacturing method thereof.

### 2. Description of Related Art

With the vigorous development of portable electronic products in recent years, the trends of the various related products are gradually towards high density, high performance, lightness, thinness, shortness and smallness. Therefore, various types of packaging processes have also been innovated to meet the requirements of lightness, thinness, shortness and smallness.

FIG. 1A and FIG. 1B are schematic cross-sectional views of a manufacturing method of conventional semiconductor package.

As shown in FIG. 1A, a wafer 1 is mounted on a carrier 13. The wafer 1 includes a plurality of chips 10. Each of the chips 10 has a first surface 10a and a second surface 10b opposite to the first surface 10a. The first surface 10a is formed with a plurality of first metal bumps 11, and the second surface 10b is formed with a plurality of second metal bumps 12.

As shown in FIG. 1B, a packaging process is performed to form a packaging layer 14 covering the plurality of chips 10 on the carrier 13.

In the aforementioned semiconductor package, in order to comply with the trend of electronic products being lightness, thinness, shortness and smallness, the thickness of the chip 10 has been designed to be more and more thinner. However, after the packaging layer 14 is formed, the wafer 1 is significantly warped due to the shrinkage of the encapsulant (as shown by the arrow in FIG. 1B), and in severe cases, the chip 10 may be damaged.

Therefore, there is a need for a solution that addresses the aforementioned shortcomings in the prior art.

### SUMMARY

In view of the aforementioned shortcomings of the prior art, the present disclosure provides an electronic package, which comprises: a plurality of electronic components each having a first side and a second side opposite to the first side, wherein the first side is formed with a plurality of first conductive bumps, the second side is formed with a plurality of second conductive bumps, and each of the plurality of electronic components is spaced apart from another one of the electronic components by a scribe line; a stress buffer disposed on the scribe line; and an encapsulation layer encapsulating the plurality of electronic components and the stress buffer, and an end surface of the stress buffer is exposed from the encapsulation layer.

The present disclosure also provides a method of manufacturing an electronic package, which comprises: providing a monolithic structure including a plurality of electronic components, wherein each of the plurality of electronic components has a first side and a second side opposite to the first side, the first side is formed with a plurality of first conductive bumps, the second side is formed with a plurality of second conductive bumps, and the plurality of electronic components are spaced apart from one another by a scribe line; disposing a stress buffer on the scribe line; and forming an encapsulation layer to encapsulate the plurality of electronic components and the stress buffer, wherein an end surface of the stress buffer is exposed from the encapsulation layer.

The aforementioned electronic package and method further including removing the stress buffer to expose the scribe line.

The aforementioned electronic package and method further including cutting the monolithic structure along the scribe line to separate each of the plurality of electronic components.

The aforementioned electronic package and method further including removing the stress buffer from the scribe line by a cleaning process.

In the aforementioned electronic package and method, the stress buffer is a water-soluble adhesive material and is formed on the scribe line through an exposure and development process.

In the aforementioned electronic package and method, each of the plurality of electronic components is formed with a plurality of conductive vias, and the plurality of conductive vias are electrically connected to the plurality of first conductive bumps and the plurality of second conductive bumps.

In the aforementioned electronic package and method, a width of the stress buffer is greater than a width of the scribe line.

In the aforementioned electronic package and method, a coefficient of thermal expansion of the stress buffer is different from a coefficient of thermal expansion of the encapsulation layer.

In the aforementioned electronic package and method, a coefficient of thermal expansion of the stress buffer is greater than a coefficient of thermal expansion of the encapsulation layer.

In the aforementioned electronic package and method, the stress buffer and the plurality of second conductive bumps are located on the same side, and a height of the stress buffer is greater than a height of each of the plurality of second conductive bumps.

In the aforementioned electronic package and method, the plurality of first conductive bumps and the plurality of second conductive bumps are metal pillars.

As can be understood from the above, in the electronic package and manufacturing method thereof according to the present disclosure, the stress buffer is disposed on the scribe line between the plurality of electronic components, and then the encapsulation layer encapsulating the plurality of electronic components and the stress buffer is formed, thereby a stress is reduced by reducing the encapsulation layer. At the same time, the stress is interrupted, a rigidity of overall structure is improved, and excessive warpage can be avoided.

### BRIEF DESCRIPTION OF THE DRAWINGS

FIG. 1A and FIG. 1B are schematic cross-sectional views of a manufacturing method of a conventional semiconductor package.

FIG. 2A to FIG. 2C are schematic cross-sectional views of an electronic package and manufacturing method thereof according to the present disclosure.

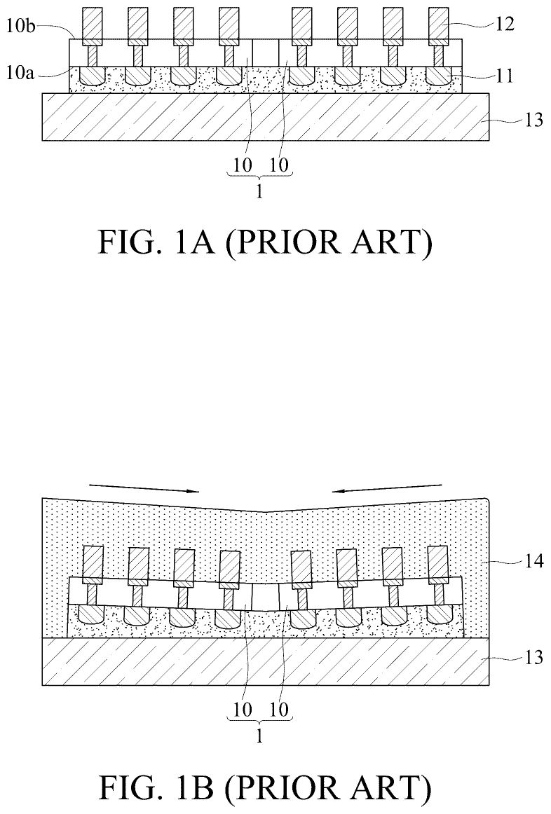

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

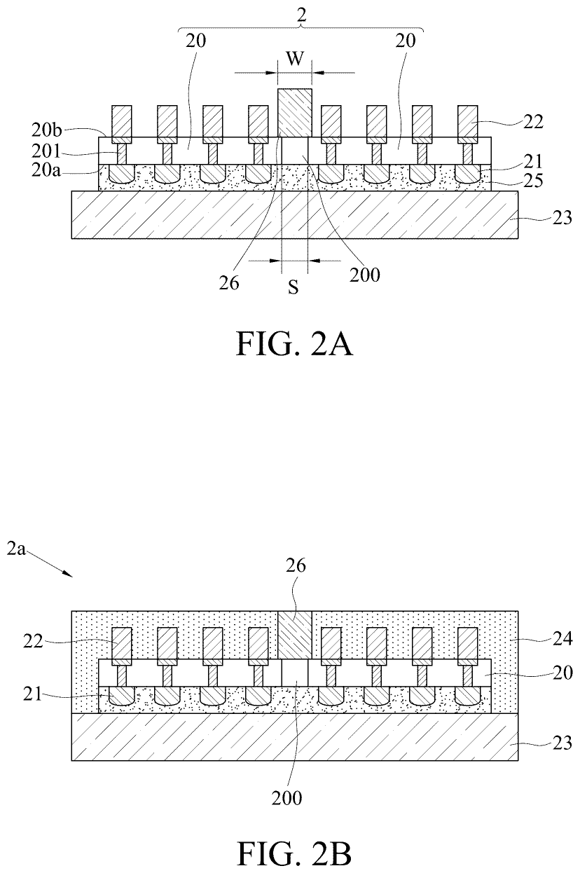

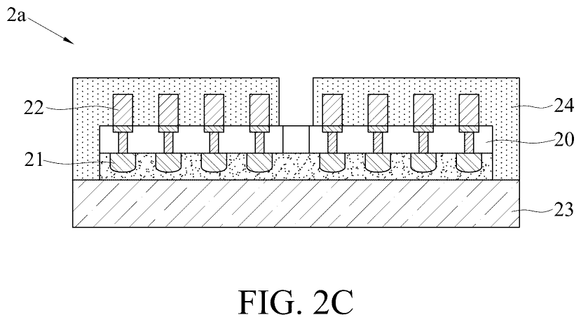

FIG. 2A to FIG. 2C are schematic cross-sectional views of a manufacturing method of an electronic package of the present disclosure.

As shown in FIG. 2A, a monolithic wafer structure 2 including a plurality of electronic components 20 is provided, the wafer structure 2 is mounted on a carrier 23, and each of the plurality of electronic components 20 is spaced apart by a scribe line.

The electronic component 20 is, for example, a semiconductor chip, which has a first side 20a and a second side 20b opposite to the first side 20a, the first side 20a is formed with a plurality of first conductive bumps 21, and the second side 20b is formed with a plurality of second conductive bump 22. A side of the wafer structure 2 having the plurality of first conductive bumps 21 is connected to the carrier 23 through an adhesive material 25, and thus the plurality of first conductive bumps 21 are embedded in the adhesive material 25. The plurality of first conductive bumps 21 and the plurality of second conductive bumps 22 are metal pillars such as copper pillars, the adhesive material 25 is, for example, an adhesive, and the carrier 23 is, for example, a temporary carrier board without electrical function.

In addition, a plurality of conductive vias 201 are formed in and penetrate the plurality of electronic components 20, and the plurality of first conductive bumps 21 and the plurality of second conductive bumps 22 are thus electrically connected by the plurality of conductive vias 201. The conductive via 201 is, for example, a through-silicon via (TSV).

Next, a stress buffer 26 is formed on the scribe line 200, and the stress buffer 26 is located on a side the same as the plurality of second conductive bumps 22. The stress buffer 26 is, for example, a water-soluble adhesive material, which can be formed on the scribe line 200 through an exposure and development process, for example.

In one embodiment, a width W of the stress buffer 26 is greater than a width S of the scribe line 200.

As shown in FIG. 2B, an encapsulation layer 24 is formed on the carrier 23 to encapsulate the plurality of electronic components 20 (including the plurality of second conductive bumps 22) and the stress buffer 26, and an end surface of the stress buffer 26 is exposed from the encapsulation layer 24.

In one embodiment, the stress buffer 26 and the encapsulation layer 24 have different coefficients of thermal expansion.

In one embodiment, a coefficient of thermal expansion of the stress buffer 26 is greater than that of the encapsulation layer 24.

In one embodiment, a height of the stress buffer 26 is greater than a height of each of the plurality of second conductive bumps 22, a stress problem caused by the stress buffer 26 being covered by the encapsulation layer 24 can be avoided.

As shown in FIG. 2C, the stress buffer 26 located on the scribe line 200 is removed to expose the scribe line 200, and the plurality of electronic components 20 (including the plurality of second conductive bumps 22) are still covered by the encapsulation layer 24. The stress buffer 26 can be removed from the scribe line 200 by a cleaning method.

Subsequently, cutting can be performed along the scribe line 200 to separate each of the plurality of electronic components 20.

The present disclosure further provides an electronic package 2a shown in FIG. 2B, which comprises: the plurality of electronic components 20, each of the plurality of electronic components 20 has the first side 20a and the second side 20b opposite to the first side 20a, wherein the first side 20a is formed with the plurality of first conductive bumps 21, the second side 20b is formed with the plurality of second conductive bumps 22, and each of the plurality of electronic components 20 is spaced apart by the scribe line 200; the stress buffer 26 disposed on the scribe line 200; and the encapsulation layer 24 encapsulating the plurality of electronic components 20 and the stress buffer 26, and the end surface of the stress buffer 26 is exposed from the encapsulation layer 24.

The plurality of electronic components 20 form the monolithic wafer structure 2. A plurality of conductive vias 201 are formed in and penetrate the plurality of electronic components 20, and thus the plurality of first conductive bumps 21 and the plurality of second conductive bumps 22 are electrically connected by the plurality of conductive vias 201.

In view of the above, in the electronic package and manufacturing method thereof according to the present disclosure, the stress buffer is disposed on the scribe line between the plurality of electronic components, and then the encapsulation layer encapsulating the plurality of electronic components and the stress buffer is formed, thereby a stress is reduced by reducing the encapsulation layer. Meanwhile, the stress is interrupted, a rigidity of overall structure is improved, and excessive warpage can be avoided.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a plurality of electronic components, each of the plurality of electronic components having a first side and a second side opposite to the first side, wherein the first side is formed with a plurality of first conductive bumps, the second side is formed with a plurality of second conductive bumps, and the plurality of electronic components is spaced apart from one another by a scribe line;
a stress buffer disposed on the scribe line; and
an encapsulation layer encapsulating the plurality of electronic components and the stress buffer, wherein an end surface of the stress buffer is exposed from the encapsulation layer.

2. The electronic package of claim 1, wherein the plurality of electronic components constitute a monolithic wafer structure.

3. The electronic package of claim 1, wherein each of the plurality of electronic components is formed with a plurality of conductive vias, and the plurality of conductive vias are electrically connected to the plurality of first conductive bumps and the plurality of second conductive bumps.

4. The electronic package of claim 1, wherein the stress buffer is formed with a water-soluble adhesive material.

5. The electronic package of claim 1, wherein a width of the stress buffer is greater than a width of the scribe line.

6. The electronic package of claim 1, wherein a coefficient of thermal expansion of the stress buffer is different from a coefficient of thermal expansion of the encapsulation layer.

7. The electronic package of claim 1, wherein a coefficient of thermal expansion of the stress buffer is greater than a coefficient of thermal expansion of the encapsulation layer.

8. The electronic package of claim 1, wherein the stress buffer and the plurality of second conductive bumps are located on the same side, and a height of the stress buffer is greater than a height of each of the plurality of second conductive bumps.

9. The electronic package of claim 1, wherein the plurality of first conductive bumps and the plurality of second conductive bumps are metal pillars.

10. A method of manufacturing an electronic package, comprising:
providing a monolithic structure including a plurality of electronic components, wherein each of the plurality of electronic components has a first side and a second side opposite to the first side, the first side is formed with a plurality of first conductive bumps, the second side is formed with a plurality of second conductive bumps, and each of the plurality of electronic components is spaced apart by a scribe line;
forming a stress buffer on the scribe line; and
forming an encapsulation layer to encapsulate the plurality of electronic components and the stress buffer, wherein an end surface of the stress buffer is exposed from the encapsulation layer.

11. The method of claim 10, further comprising removing the stress buffer to expose the scribe line.

12. The method of claim 11, further comprising cutting along the monolithic structure the scribe line to separate each of the plurality of electronic components.

13. The method of claim 11, further comprising removing the stress buffer from the scribe line by a cleaning process.

14. The method of claim 10, wherein the stress buffer is a water-soluble adhesive material and is formed on the scribe line through an exposure and development process.

15. The method of claim 10, wherein each of the plurality of electronic components is formed with a plurality of conductive vias, and the plurality of conductive vias are electrically connected to the plurality of first conductive bumps and the plurality of second conductive bumps.

16. The method of claim 10, wherein a width of the stress buffer is greater than a width of the scribe line.

17. The method of claim 10, wherein a coefficient of thermal expansion of the stress buffer is different from a coefficient of thermal expansion of the encapsulation layer.

18. The method of claim 10, wherein a coefficient of thermal expansion of the stress buffer is greater than a coefficient of thermal expansion of the encapsulation layer.

19. The method of claim 10, wherein the stress buffer and the plurality of second conductive bumps are located on the same side, and a height of the stress buffer is greater than a height of each of the plurality of second conductive bumps.

20. The method of claim 10, wherein the plurality of first conductive bumps and the plurality of second conductive bumps are metal pillars.
